(19) United States
(12) Patent Application Publication
(10) Pub. No.: US 2015/0359090 A1
(43) Pub. Date: Dec. 10, 2015

(54) CIRCUIT SUBSTRATE AND METHOD FOR MANUFACTURING CIRCUIT SUBSTRATE

(71) Applicant: IBIDEN CO., LTD., Ogaki (JP)

(72) Inventor: Satoshi WATANABE, Ogaki (JP)

(73) Assignee: IBIDEN CO., LTD., Ogaki (JP)

(21) Appl. No.: 14/731,636

(22) Filed: Jun. 5, 2015

(30) Foreign Application Priority Data
Jun. 6, 2014 (JP) 2014-117386

(51) Int. Cl. H05K 1/02; H05K 3/02

(52) U.S. Cl. CPC H05K 1/0296; H05K 3/025; H05K 3/027

(57) ABSTRACT

A circuit substrate includes an insulating layer, a conductor layer laminated on the insulating layer and including a plane layer portion, and a solder resist layer formed on the insulating layer such that the solder resist layer is covering the conductor layer. The plane layer portion of the conductor layer has recess portions or opening portions, and the solder resist layer includes recessed portions covering the recess portions or opening portions of the plane layer portion.

### CROSS-REFERENCE TO RELATED APPLICATIONS

The present application is based upon and claims the benefit of priority to Japanese Patent Application No. 2014-117386, filed Jun. 6, 2014, the entire contents of which are incorporated herein by reference.

### BACKGROUND OF THE INVENTION

1. Field of the Invention

The present invention relates to a circuit substrate in which a conductor layer that is laminated on an insulating layer is covered by a solder resist layer, and relates to a method for manufacturing the circuit substrate.

2. Description of Background Art

A circuit substrate may be provided with a projection that projects upward from a solder resist layer (for example, see Japanese Patent Laid-Open Publication No. HEI 7-38230). The entire contents of this publication are incorporated herein by reference.

### SUMMARY OF THE INVENTION

According to one aspect of the present invention, a circuit substrate includes an insulating layer, a conductor layer laminated on the insulating layer and including a plane layer portion, and a solder resist layer formed on the insulating layer such that the solder resist layer is covering the conductor layer. The plane layer portion of the conductor layer has recess portions or opening portions, and the solder resist layer includes recessed portions covering the recess portions or opening portions of the plane layer portion.

According to another aspect of the present invention, a method for manufacturing a circuit substrate includes laminating a conductor layer on an insulating layer, forming a plane layer portion in the conductor layer, forming recess portions or opening portions in the plane layer portion, and forming a solder resist layer on the insulating layer such that the solder resist layer covers the conductor layer. The forming of the solder resist layer includes forming the solder resist layer on the conductor layer such that the solder resist layer has recessed portions covering the recess portions or opening portions of the plane layer portion.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view of a circuit substrate according to an embodiment of the present invention;

FIG. 2 is a cross-sectional view of the circuit substrate;

FIG. 3 is a perspective view of the circuit substrate excluding a solder resist layer;

FIG. 4A is a plan view of a plane layer;

FIG. 4B is a cross-sectional view of the plane layer along a line A-A;

FIGS. 5A-5D are cross-sectional views illustrating manufacturing processes of the circuit substrate;

FIGS. 6A and 6B are cross-sectional views illustrating manufacturing processes of the circuit substrate;

FIGS. 7A and 7B are cross-sectional views illustrating manufacturing processes of the circuit substrate;

FIGS. 8A and 8B are cross-sectional views illustrating manufacturing processes of the circuit substrate;

FIGS. 9A and 9B are cross-sectional views illustrating manufacturing processes of the circuit substrate; and

FIG. 10 is a cross-sectional view of a circuit substrate according to a modified embodiment.

### DETAILED DESCRIPTION OF THE EMBODIMENTS

The embodiments will now be described with reference to the accompanying drawings, wherein like reference numerals designate corresponding or identical elements throughout the various drawings.

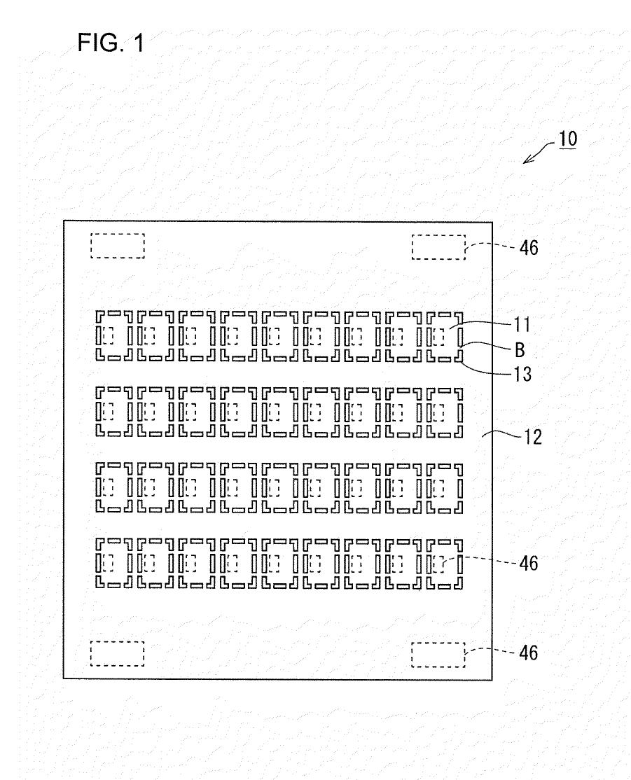

In the following, an embodiment of the present invention is described based on FIG. 1-9B. As illustrated in FIG. 1, a circuit substrate 10 of the present embodiment is a multi-piece substrate that includes multiple product regions 11, which are individual wiring substrates, and a non-product region 12. The product regions 11 are arranged at intervals lengthwise and widthwise. The non-product region 12 is arranged to include portions positioned between the product regions 11 and a peripheral edge portion that surrounds the product regions 11. Around each product region 11, multiple slits 13 for individually taking out a wiring substrate from the circuit substrate 10 are formed along an outer periphery of the product region 11, and bridges (B) are each formed between adjacent slits (13, 13).

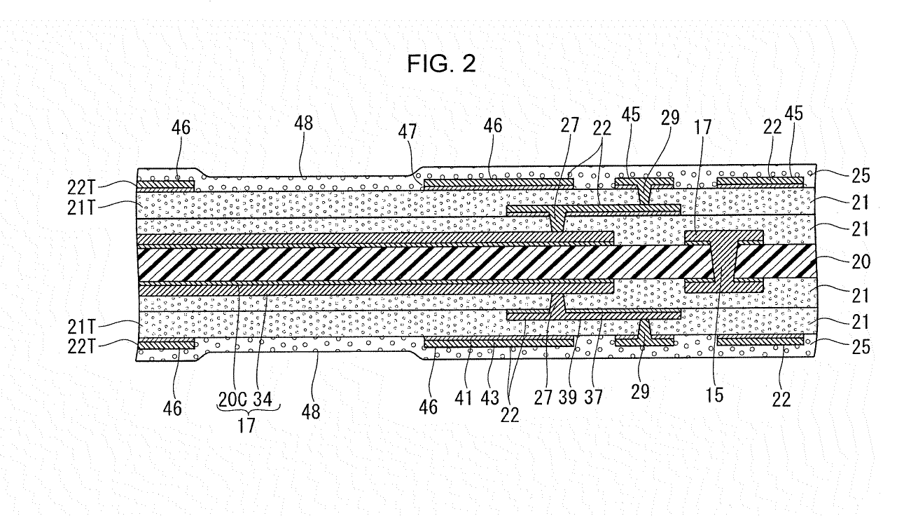

As illustrated in FIG. 2, the circuit substrate 10 is formed to have a laminate structure in which build-up insulating layers 21 and build-up conductor layers 22 are alternately laminated on both front and back sides of a core substrate 20. A core conductor layer 17 is formed on each of both front and back sides of the core substrate 20. The core substrate 20 and the build-up insulating layers 21 are formed of an insulating material. Further, the core conductor layers 17 and the build-up conductor layers 22 are formed of metal (such as copper). The front side core conductor layer 17 and the back side core conductor layer 17 are connected by a via conductor (filled via) 15 that penetrates through the core substrate 20.

The build-up conductor layers (22, 22) are connected to each other by a via conductor 29 that penetrates through the build-up insulating layer 21. Further, an innermost build-up conductor layer 22, which is closest to the core substrate 20, and the core conductor layer 17 are connected by a via conductor 27 that penetrates through an innermost build-up insulating layers 21.

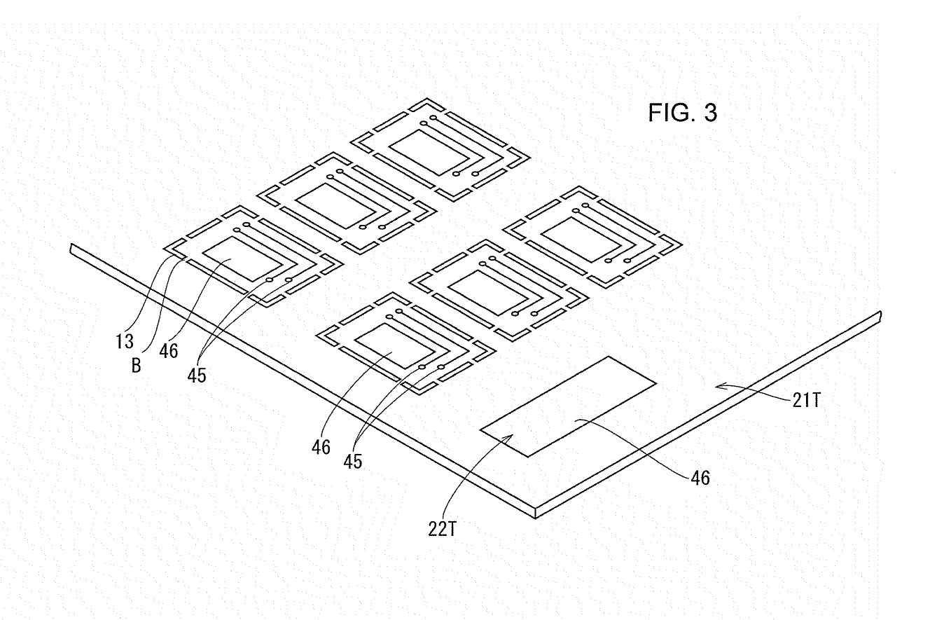

As illustrated in FIG. 3, a signal layer 45 and a plane layer 46 are formed in an outermost build-up conductor layer (22T) that is farthest from the core substrate 20 among the build-up conductor layers 22. The plane layer 46 is formed in the product regions 11 and in the non-product region 12. The plane layer 46 formed in the product regions 11 is provided for power supply, grounding or heat dissipation. The plane layer 46 formed in the non-product region 12 is provided for potential inspection.

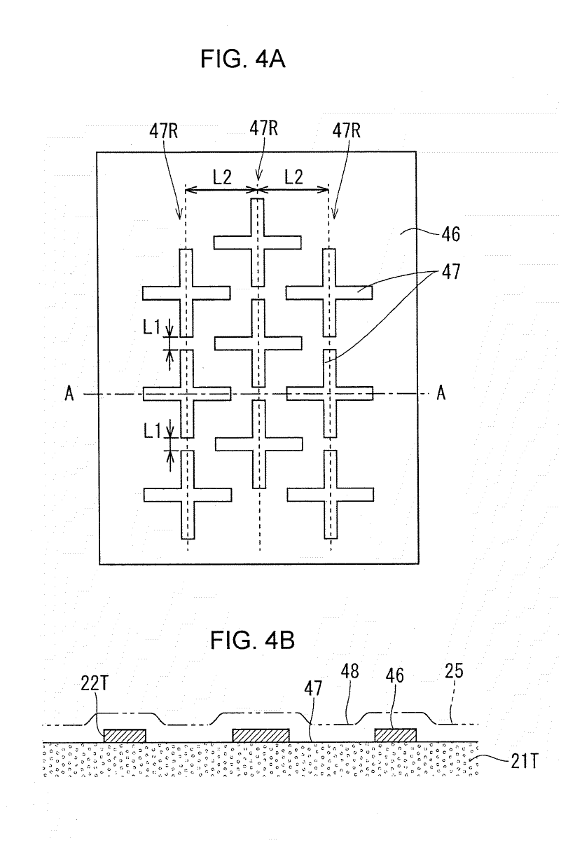

As illustrated in the plan view of FIG. 4A, the plane layer 46 has multiple openings 47. Here, the island-shaped signal layer 45 such as a land or a pad is not formed on an inner side of each of the openings 47. Each of the openings 47, over its entire interior, exposes an outermost build-up insulating layer (21T) that is arranged on an immediate inner side of the outermost build-up conductor layer (22T). In the present embodiment, the outermost build-up insulating layer (21T) corresponds to an “insulating layer” according to an embodiment of the present invention; and the outermost build-up conductor layer (22T) corresponds to a “conductor layer” according to an embodiment of the present invention.

The openings 47 are each formed in a cross shape in which two slits each having a width of 0.25 mm and a length of 1.7 mm bisect each other at a right angle. Further, the openings 47 are arranged in a staggered pattern. Specifically, multiple opening arrays (47R) are arranged in parallel, each of the opening arrays (47R) including multiple openings 47 that are aligned such that slits each being one of the above-described two slits of each of the openings are arranged on the same straight line. An interval (L1) between adjacent openings (47, 47) in each of the opening arrays (47R) is 0.25 mm. Further, an interval (L2) between adjacent opening arrays (47R, 47R) is 2.0 mm.

As illustrated in FIG. 2, a solder resist layer 25 is formed on the outermost build-up conductor layer (22T). Multiple holes for pads (not illustrated in the drawings) are formed in the solder resist layer 25. Portions of the outermost build-up conductor layer (22T) are positioned in the holes for pads and become pads for electrical conduction (not illustrated in the drawings). Further, as illustrated in FIG. 4B, recesses 48 that are recessed toward the core substrate 20 side are formed in portions of the solder resist layer 25 that cover the openings 47.

The circuit substrate 10 of the present embodiment is manufactured as follows.

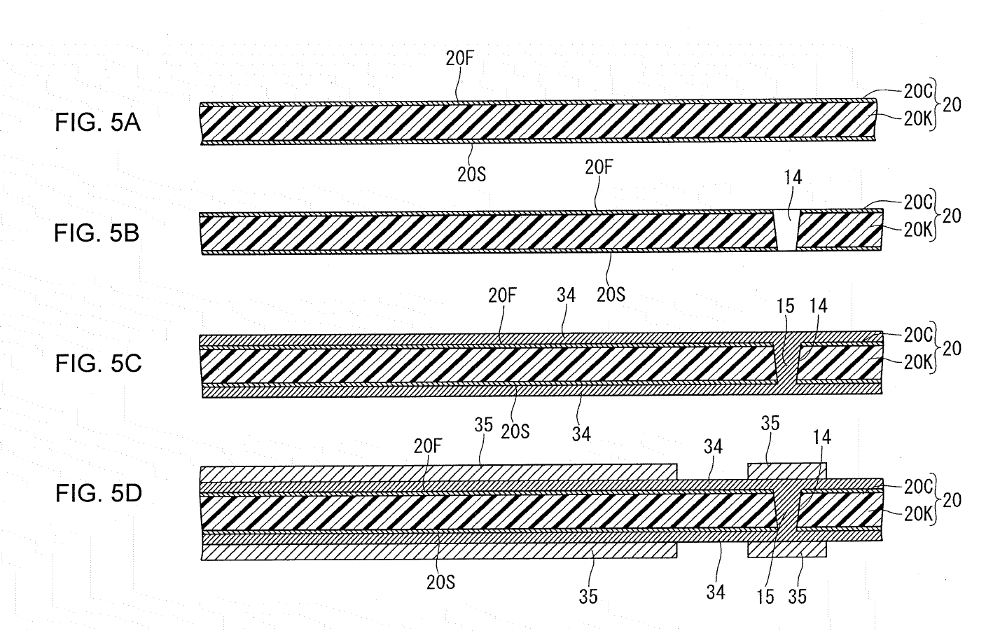

(1) As illustrated in FIG. 5A, first, the core substrate 20 is prepared. The core substrate 20 is obtained by laminating a copper foil (20C) on both front and back surfaces of an insulating base material (20K) that is made of epoxy resin or BT (bismaleimide triazine) resin and a reinforcing material such as a glass cloth.

(2) As illustrated in FIG. 5B, a via hole 14 that penetrates through the copper foil (20C) on an F surface (20F) side and the insulating base material (20K) to expose the copper foil (20C) on an S surface (20S) side is formed by irradiating, for example, CO2 laser from the F surface (20F) side to the core substrate 20, the F surface (20F) being a front surface of the core substrate 20 and the S surface (20S) being a back surface of the core substrate 20.

(3) An electroless plating treatment is performed. An electroless plating film (not illustrated in the drawings) is formed on the copper foil (20C) and on an inner surface of the core through hole 14.

(4) As illustrated in FIG. 5C, an electrolytic plating treatment is performed. The core through hole 14 is filled with electrolytic plating and the via conductor (filled via) 15 is formed. Electrolytic plating films (34, 34) are respectively formed on the two electroless plating films (not illustrated in the drawings) on the F surface (20F) and the S surface (20S) of the core substrate 20.

(5) As illustrated in FIG. 5D, an etching resist 35 of a predetermined pattern is formed on each of the electrolytic plating films (34, 34) on the F surface (20F) and the S surface (20S) of the core substrate 20.

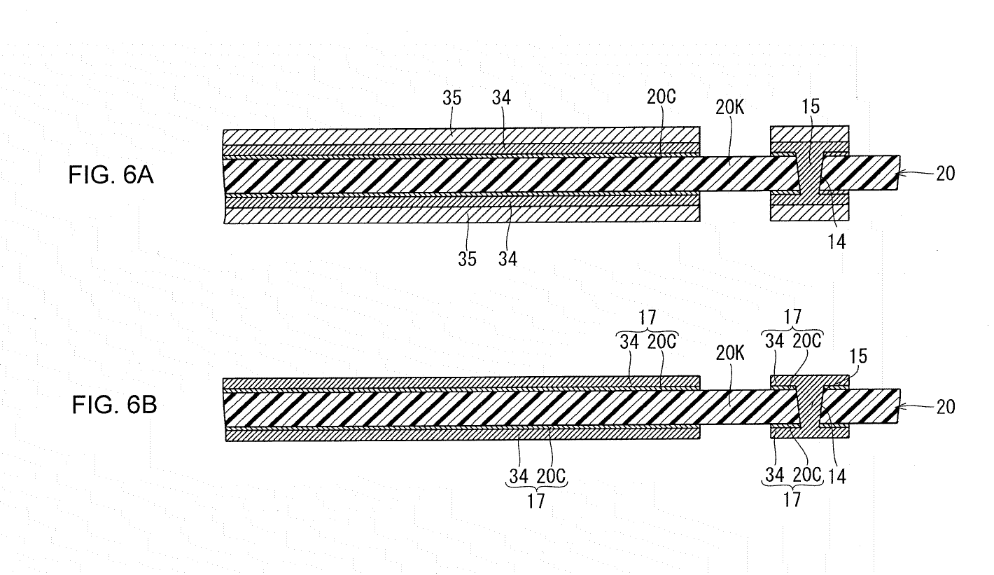

(6) An etching process is performed. The electrolytic plating film 34, the electroless plating film (not illustrated in the drawings) and the copper foil (20C) that are exposed from the etching resist 35 are removed (see FIG. 6A). The core conductor layers 17 are formed on the front and back surfaces of the core substrate 20 by the remaining electrolytic plating film 34, electroless plating film and copper foil (20C), as illustrated in FIG. 6B. Then, the front side core conductor layer 17 and the back side core conductor layer 17 are in a state of being connected by the through-hole conductor 15.

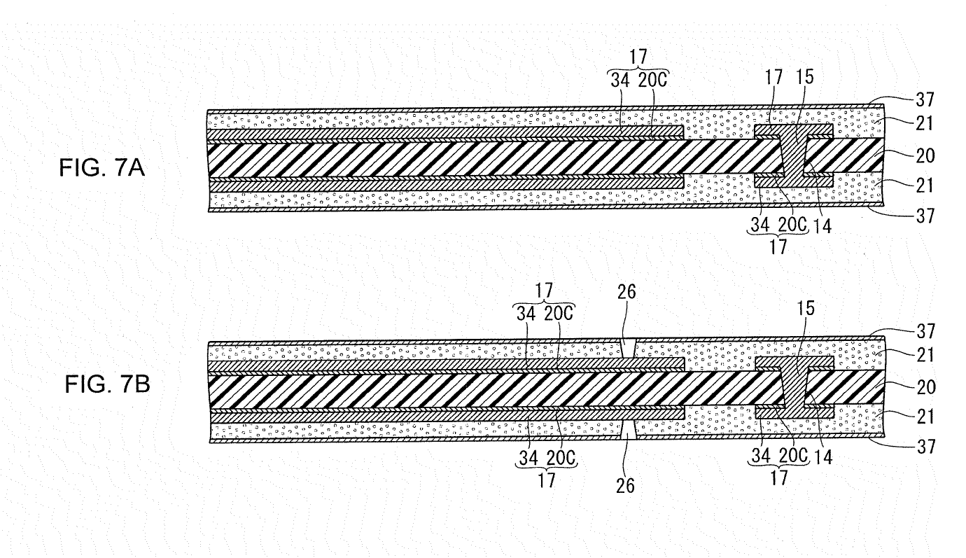

(7) As illustrated in FIG. 7A, a prepreg (a resin sheet of a B-stage formed by impregnating a core material with resin) as a build-up insulating layer 21 and a copper foil 37 are laminated on each of the front and back core conductor layers 17. Then, the resulting substrate is hot-pressed. In this case, a region where the core conductor layer 17 is not formed is filled with the prepreg. Instead of the prepreg, it is also possible to use a resin film that does not contain a core material as the build-up insulating layer 21. In this case, without laminating a copper foil, a conductor layer can be directly formed on the resin film using a semi-additive method.

(8) As illustrated in FIG. 7B, CO2 laser is irradiated to the front and back copper foils 37 and via holes 26 that penetrate through the copper foils 37 and the build-up insulating layers 21 are formed. Then, insides of the via holes 26 are cleaned using an oxidation agent such as permanganate.

(9) An electroless plating treatment is performed. An electroless plating film (not illustrated in the drawings) is formed on the copper foil 37 and on an inner surface of the via hole 26.

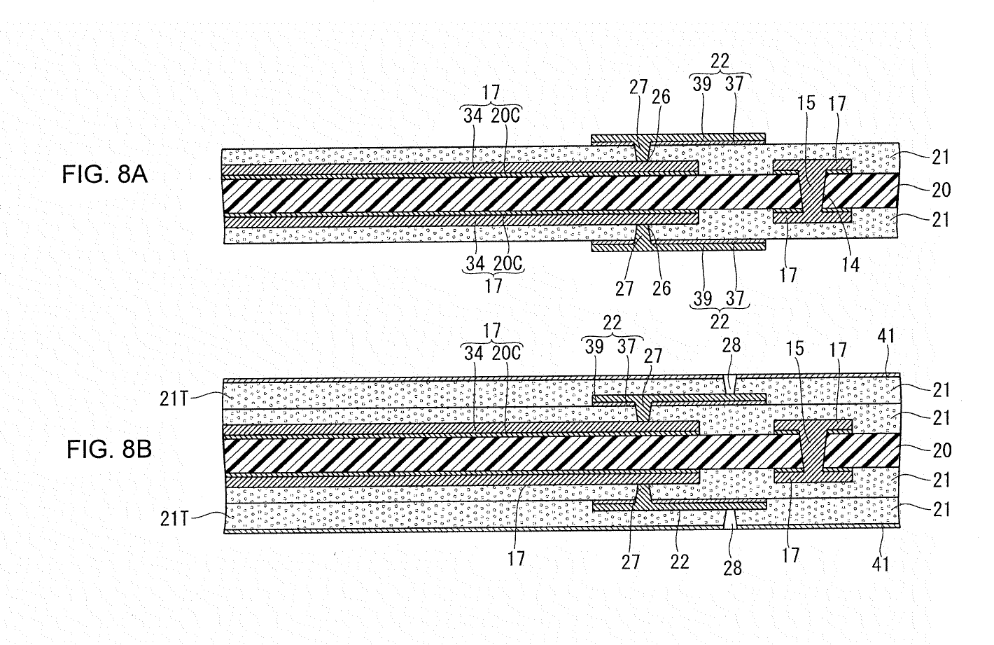

(10) In the same manner as illustrated in FIGS. 5C and 5D, an electrolytic plating film 39 (see FIG. 8A) is formed on the copper foil 37, and a via conductor 27 is formed in the via hole 26 and an etching resist (not illustrated in the drawings) of a predetermined pattern is formed on the electrolytic plating film 39. Next, in the same manner as illustrated in FIGS. 6A and 6B, by performing an etching process, a build-up conductor layer 22 (see FIG. 8A) is formed by portions of the electrolytic plating film 39, the electroless plating film and the copper foil 37 that are covered by the etching resist. Thereafter, the etching resist is removed. Then, the build-up conductor layer 22 and the core conductor layer 17 are in a state of being connected by the via conductor 27.

(11) In the same manner as illustrated in FIGS. 7A and 7B, a prepreg as the outermost build-up insulating layer (21T) and a copper foil 41 are laminated on the build-up conductor layer 22, and a via hole 28 that penetrates through the copper foil 41 and the outermost build-up insulating layer (21T) is formed (see FIG. 8B). In this case, a region where the build-up conductor layer 22 is not formed is filled with the prepreg.

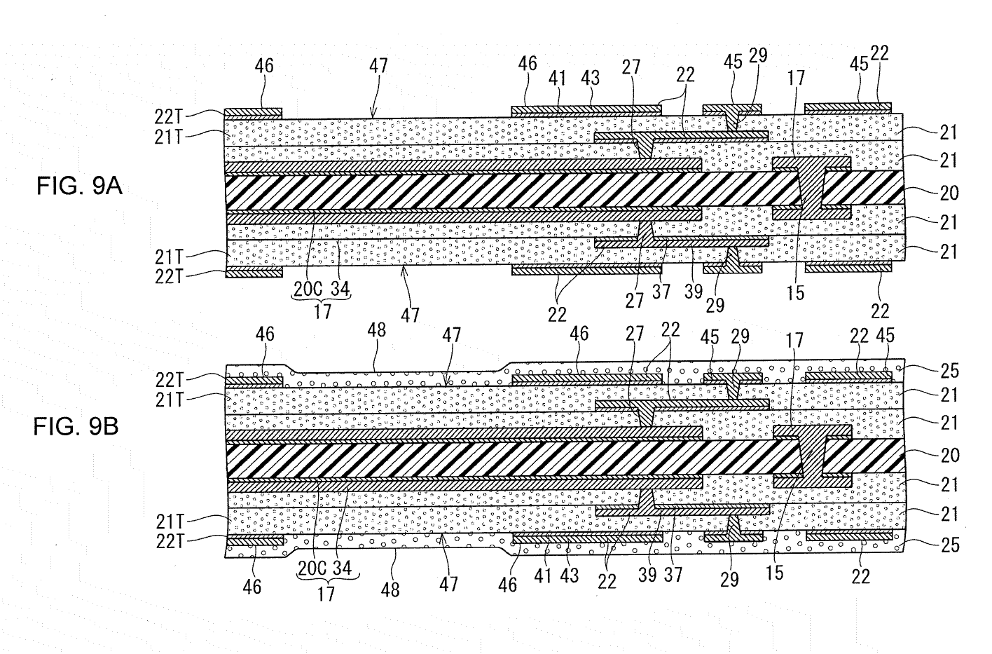

(12) In the same manner as illustrated in FIGS. 5C and 5D, an electrolytic plating film 43 (see FIG. 9A) is formed on the copper foil 41, and a via conductor 29 is formed in the via hole 28 and an etching resist (not illustrated in the drawings) of a predetermined pattern is formed on the electrolytic plating film 43. Next, in the same manner as illustrated in FIGS. 6A and 6B, by performing an etching process, the outermost build-up conductor layer (22T) (see FIG. 9A) is formed by portions of the electrolytic plating film 43, the electroless plating film and the copper foil 41 that are covered by the etching resist. Thereafter, the etching resist is removed. In this case, the signal layer 45 and the plane layer 46 are formed in the outermost build-up conductor layer (22T) (see FIG. 3), and the openings 47 are formed in the plane layer 46 (see FIG. 4A). Further, the signal layer 45 is in a state of being connected by the via conductor 29 to the build-up conductor layer 22 that is one layer below the outermost build-up conductor layer.

(13) As illustrated in FIG. 9B, the solder resist layer 25 is laminated on the outermost build-up conductor layer (22T). In this case, the recesses 48 that are recessed toward the core substrate 20 side are formed in portions of the solder resist layer 25 that cover the openings 47.

(14) By router processing or the like, the slits 13 (see FIG. 1) are formed along each of the product regions 11. As a result, the circuit substrate 10 is completed.

The description about the structure and the manufacturing method of the circuit substrate 10 of the present embodiment is as given above. Next, an operation effect of the circuit substrate 10 is described.

In the circuit substrate 10 of the present embodiment, portions of the solder resist layer 25 that cover the openings 47 are recessed. Thereby, the recesses 48 are formed in the solder resist layer 25. As a result, when multiple circuit substrates 10 are stacked, that the circuit substrates 10 stick to each other is suppressed, and the circuit substrates 10 can be easily taken out one by one. In addition, in the circuit substrate 10 of the present embodiment, the openings 47 are formed in the plane layer 46 of the outermost build-up conductor layer (22T). Thereby, the solder resist layer 25 can be recessed. Therefore, as compared to the case where a projection that projects upward is provided in a solder resist layer as in a conventional circuit substrate, the circuit substrate 10 can be made thin.

Further, in the present embodiment, each of the openings 47, over its entire interior, exposes the outermost build-up insulating layer (21T). Therefore, the solder resist layer 25 can be recessed over the entire interior of each of the openings 47.

Further, the openings 47 are formed in the product regions 11 and the non-product region 12. Therefore, that the circuit substrates 10 stick to each other can be suppressed by both the product regions 11 and the non-product region 12. In particular, the openings 47 are formed in the product regions 11. Thereby, sticking between the product regions 11 can be suppressed, and damage and the like to the products (that is, wiring substrates) can be suppressed.

Further, the openings 47 are each formed in a cross shape in a plan view. Therefore, as compared to a case where the openings are each formed in a circular shape, a range in which sticking between the circuit substrates 10 can be suppressed by one opening can be widened. In addition, the openings 47 are arranged in a staggered pattern. Thereby, that the openings 47 are arranged biased toward the plane layer 46 can be suppressed and sticking between the circuit substrates 10 can be effectively suppressed.

### Other Embodiments

The present invention is not limited to the above-described embodiment. For example, embodiments described below are also included in the technical scope of the present invention. Further, in addition to the embodiments described below, the present invention can also be embodied in various modified forms within the scope without departing from the spirit of the present invention.

(1) In the above embodiment, a planar shape of each of the openings 47 is a cross shape. However, the planar shape of each of the openings 47 may also be a circular shape or a polygonal shape. Further, the slits may radially extend to form a star.

(2) In the above embodiment, the openings 47 are arranged in a staggered pattern. However, the openings 47 may also be randomly arranged.

(3) In the above embodiment, the circuit substrate 10 may also be a coreless substrate that does not have the core substrate 20.

(4) In the above embodiment, the plane layer 46 is formed in the product regions 11 and the non-product region 12. However, the plane layer 46 may also be formed only in the product regions 11 or only in the non-product region 12.

(5) In the above embodiment, the “circuit substrate” according to an embodiment of the present invention is a multi-piece substrate that has the non-product region 12 and the product regions 11. However, the “circuit substrate” may also be a wiring substrate, the entirety of which forms one product region.

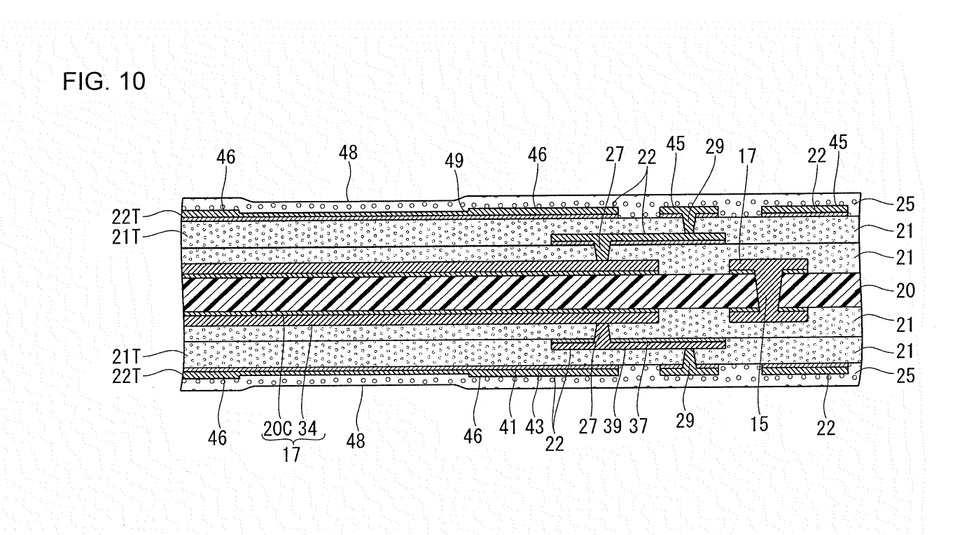

(6) In the above embodiment, the plane layer 46 is formed to have the openings 47. However, as illustrated in FIG. 10, the plane layer 46 may also be formed to have multiple recesses 49 on an outward surface. This structure also allows the recesses 48 to be formed in the solder resist layer 25. As a result, when the circuit substrates 10 are stacked, that the circuit substrates 10 stick to each other can be suppressed, and the circuit substrates 10 can be easily taken out one by one.

In a conventional circuit substrate, there may be a problem that, due to the projection, a thickness of the circuit substrate is increased. On the other hand, when the projection is eliminated from the conventional circuit substrate, there may be a problem that, when the circuit substrates are stacked on each other, solder resist layers between an upper side circuit substrate and a lower side circuit substrate stick to each other so that it is difficult to take out the circuit substrates one by one.

A circuit substrate according to an embodiment of the present invention can be made thin and can be easily taken out one by one from a state in which the circuit substrates are stacked, and another embodiment of the present invention is a method for manufacturing the circuit substrate.

A circuit substrate according to one aspect of the present invention includes: an insulating layer; a conductor layer that is laminated on the insulating layer; and a solder resist layer that covers the conductor layer. A plane layer having multiple recesses or multiple openings is formed in the conductor layer. Portions of the solder resist layer that cover the recesses or the openings are recessed.

Obviously, numerous modifications and variations of the present invention are possible in light of the above teachings. It is therefore to be understood that within the scope of the appended claims, the invention may be practiced otherwise than as specifically described herein.

What is claimed is:

1. A circuit substrate, comprising:
an insulating layer;
a conductor layer laminated on the insulating layer and comprising a plane layer portion; and
a solder resist layer formed on the insulating layer such that the solder resist layer is covering the conductor layer,
wherein the plane layer portion of the conductor layer has a plurality of recess portions or a plurality of opening portions, and the solder resist layer includes a plurality of recessed portions covering the recess portions or opening portions of the plane layer portion.

2. A circuit substrate according to claim 1, wherein the plane layer portion of the conductor layer has the plurality of opening portions formed such that each of the opening portions is exposing a surface of the insulating layer, and the recessed portions of the solder resist layer are recessed substantially over entire interiors of the opening portions, respectively.

3. A circuit substrate according to claim 1, wherein the solder resist layer is formed on the insulating layer such that the solder resist layer is covering a plurality of product regions each of which forms a wiring substrate, and a non-product region between the product regions and in a peripheral edge portion surrounding the plurality of product regions, and the conductor layer has the plane layer portion in a plurality such that the plurality of plane layer portions is positioned in the product regions and the non-product region, respectively.

4. A circuit substrate according to claim 1, wherein each of the recess portions or opening portions has a cross shape.

5. A circuit substrate according to claim 1, wherein the plurality of recess portions or the plurality of opening portions is positioned in a staggered pattern in the plane layer portion.

6. A circuit substrate according to claim 2, wherein the solder resist layer is formed on the insulating layer such that the solder resist layer is covering a plurality of product regions each of which forms a wiring substrate, and a non-product region between the product regions and in a peripheral edge portion surrounding the plurality of product regions, and the conductor layer has the plane layer portion in a plurality such that the plurality of plane layer portions is positioned in the product regions and the non-product region, respectively.

7. A circuit substrate according to claim 2, wherein each of the opening portions has a cross shape.

8. A circuit substrate according to claim 2, wherein the plurality of opening portions is positioned in a staggered pattern.

9. A circuit substrate according to claim 3, wherein each of the recess portions or opening portions has a cross shape.

10. A circuit substrate according to claim 3, wherein the plurality of recess portions or plurality of opening portions is positioned in a staggered pattern.

11. A circuit substrate according to claim 4, wherein the plurality of recess portions or plurality of opening portions is positioned in a staggered pattern.

12. A circuit substrate according to claim 6, wherein each of the recess portions or opening portions has a cross shape.

13. A circuit substrate according to claim 12, wherein the plurality of recess portions or the plurality of opening portions is positioned in a staggered pattern in the plane layer portion.

14. A circuit substrate according to claim 7, wherein the plurality of recess portions or the plurality of opening portions is positioned in a staggered pattern in the plane layer portion.

15. A circuit substrate according to claim 9, wherein the plurality of recess portions or the plurality of opening portions is positioned in a staggered pattern in the plane layer portion.

16. A method for manufacturing a circuit substrate, comprising:
laminating a conductor layer on an insulating layer;
forming a plane layer portion in the conductor layer;
forming a plurality of recess portions or a plurality of opening portions in the plane layer portion; and
forming a solder resist layer on the insulating layer such that the solder resist layer covers the conductor layer,
wherein the forming of the solder resist layer comprises forming the solder resist layer on the conductor layer such that the solder resist layer has a plurality of recessed portions covering the recess portions or opening portions of the plane layer portion.

17. A method for manufacturing a circuit substrate according to claim 16, wherein the laminating of the conductor layer includes the forming of the plane layer and the forming of the recess portions or opening portions.

18. A method for manufacturing a circuit substrate according to claim 16, wherein the forming of the recess portions or opening portions in the plane layer portion comprises forming the plurality of opening portions such that each of the opening portions exposes a surface of the insulating layer, and the forming of the solder resist layer comprises forming the recessed portions of the solder resist layer such that the recessed portions are recessed substantially over entire interiors of the opening portions, respectively.

19. A method for manufacturing a circuit substrate according to claim 16, wherein the forming of the solder resist layer comprises forming the solder resist layer on the insulating layer such that the solder resist layer covers a plurality of product regions each of which forms a wiring substrate, and a non-product region between the product regions and in a peripheral edge portion surrounding the plurality of product regions, and the forming of the plane layer portion comprises forming the plane layer portion in a plurality such that the plurality of plane layer portions is positioned in the product regions and the non-product region, respectively.

20. A method for manufacturing a circuit substrate according to claim 16, wherein the forming of the recess portions or opening portions comprises forming the plurality of recess portions or the plurality of opening portions in a staggered pattern in the plane layer portion.
